(19) United States
(12) Patent Application Publication
(10) Pub. No.: US 2025/0259691 A1
(43) Pub. Date: Aug. 14, 2025

(54) DYNAMIC THRESHOLD COMPUTATION FOR GATE SCAN

(71) Applicant: Micron Technology, Inc., Boise, ID (US)

(72) Inventors: Lei Lin, Fremont, CA (US); Luis Iam, San Jose, CA (US)

(21) Appl. No.: 19/048,453

(22) Filed: Feb. 7, 2025

Related U.S. Application Data
(60) Provisional application No. 63/551,733, filed on Feb. 9, 2024.

(51) Int. Cl. G11C 29/12; G11C 29/44; G11C 29/46

(52) U.S. Cl. CPC G11C 29/1201; G11C 29/44; G11C 29/46

(57) ABSTRACT

This disclosure configures a memory sub-system controller to dynamically compute a select gate (SG) scan threshold. The controller accesses a default cadence criterion associated with an individual portion of a set of memory components and computes a new cadence criterion for the individual portion of the set of memory components based on the default cadence criterion. The controller determines that current cadence information for the individual portion of the set of memory components satisfies the new cadence criterion. The controller, in response to determining that current cadence information for the individual portion of the set of memory components satisfies the new cadence criterion, applies a memory operation to test reliability of the individual portion and selectively retires the individual portion based on a result of testing the reliability of the individual portion.

### PRIORITY APPLICATION

This application claims the benefit of priority to U.S. Provisional Application Ser. No. 63/551,733, filed Feb. 9, 2024, which is incorporated herein by reference in its entirety.

### TECHNICAL FIELD

Examples of the disclosure relate generally to memory sub-systems and, more specifically, to providing adaptive media management for memory components, such as memory dies.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various examples of the disclosure.

FIG. 1 is a block diagram illustrating an example computing environment including a memory sub-system, in accordance with some examples.

FIG. 2 is a block diagram of an example table used to perform adaptive media management operations, in accordance with some examples.

FIG. 3 is a block diagram of an example of a timing diagram of the adaptive media management operations, in accordance with some examples.

FIG. 4 is a flow diagram of an example method of performing adaptive media management operations, in accordance with some examples.

FIG. 5 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

Examples of the present disclosure configure a system component, such as a memory sub-system controller, to perform one or more memory operations (e.g., select gate (SG) scan operations) that test reliability of memory components based on one or more dynamically computed cadence criteria. For example, the controller can access a default cadence criterion associated with one or more memory components (e.g., one or more memory die or blocks) and can compute a new or updated cadence criterion based on current parameters associated with the one or more memory components (e.g., current number of reads and/or current temperature). The controller can then perform the SG scan operations based on the new or updated cadence criterion being satisfied by current parameters of the one or more memory components to test reliability of the one or more memory components. This way, the one or more memory operations are performed based on dynamic factors specific to current operations of the one or more memory components, which improves the overall efficiency of the memory sub-system.

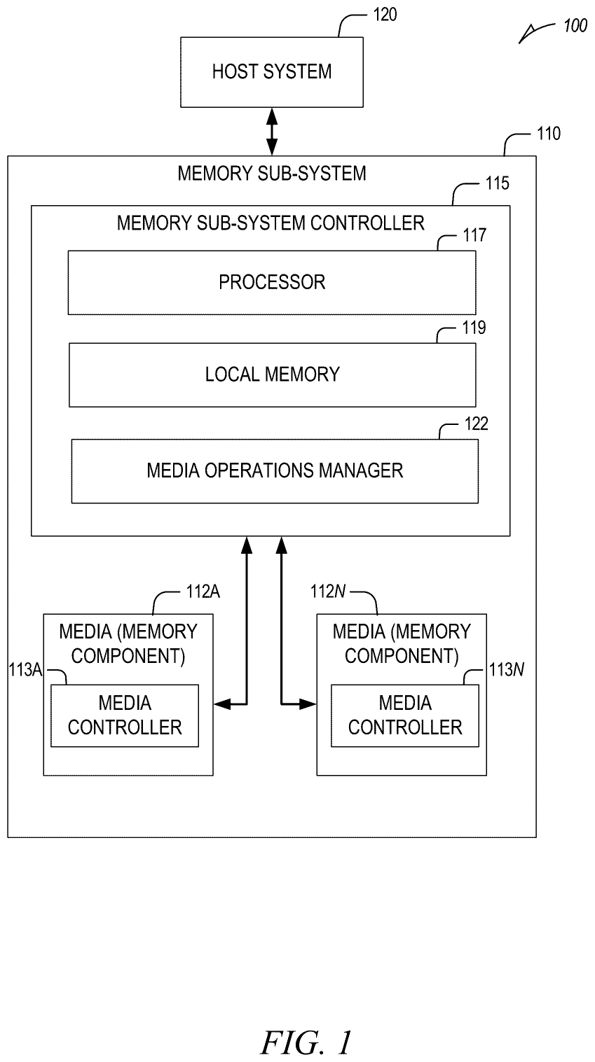

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scans read all data and identify the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., negative-and (NAND) devices), each plane is comprised of a set of physical blocks. For some memory devices, blocks are the smallest area than can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory devices combined with local embedded controllers for memory management within the same memory device package.

When certain portions of the memory components of conventional memory sub-systems start reaching their end of life, such as when a certain number (e.g., 1000) of program-erase (PE) cycles are performed on the portions, additional tests need to be performed to test the reliability of the portions. If the portions successfully pass the additional tests (e.g., SG scan operations), the portions are placed in a free block pool to allow data to be programmed to the portions. If the portions fail the additional tests (e.g., SG scan operations), the portions are marked bad to prevent data from being subsequently programmed to these portions. There are certain areas within each NAND block called SGD (select gate drain) and SGS (select gate source) that can have a charge loss as NAND undergoes multiple PE cycles. The SG scan operations can be performed to detect if this degradation has happened when the NAND block has reached each predefined erase cycle and/or when a certain default number of read operations have been performed on the NAND block and/or die.

As part of the SG scan operations, a low VT (voltage threshold) scan is performed on the SGS/SGD of a target block to test if the scan fails. If this scan fails, a voltage recovery operation can be performed to improve the health of the memory block. Then, a high VT scan is performed on the SGS/SGD of the target block to test if the scan fails. The combination of the low VT and high VT application to the target block to determine if the target block is operating within a desired voltage range enables the detection of memory blocks that are likely to fail and provides an indication or measure of reliability of the target block as results of the SG scan operations.

In some cases, the memory controllers determine whether the current number of read operations associated with a memory portion or component corresponds to a predefined default threshold. If so, the memory controller performs SG scan operations to test the reliability of the portion (e.g., before returning the portion to the free block pool). The default threshold is usually set at device manufacture and may not meet the specific demands of the host systems on which the device is implemented. This one-size-fits all approach fails to address the needs of every system and can be overly conservative (resulting in unnecessary SG scan operations) or not conservative enough (resulting in poor memory performance).

Examples of the present disclosure address the above and other deficiencies by providing a memory controller that can dynamically control the cadence criterion or criteria (e.g., thresholds) that are used to trigger certain memory operations (e.g., SG scan operations) for testing reliability of the memory component(s). For example, the default cadence criterion (e.g., default threshold number of read operations) can be updated based on a current read measure (e.g., current read frequency or current number of read operations performed in a given time interval) and/or based on temperature. This way, if the current read measure falls within a first range of values, a new cadence criterion can be used corresponding to a first threshold and if the current read measure falls within a second range of values, a different cadence criterion can be used corresponding to a second threshold. In some cases, the new cadence criterion is computed as a function or ratio of the current number of read operations and the default cadence criterion (default number of read operations). In this way, the controller can improve the storage and retrieval of data from the memory components and reduce errors.

In some examples, the memory controller accesses a default cadence criterion associated with an individual portion of the set of memory components. The memory controller computes a new cadence criterion for the individual portion of the set of memory components based on the default cadence criterion and determines that current cadence information for the individual portion of the set of memory components satisfies the new cadence criterion. The memory controller, in response to determining that current cadence information for the individual portion of the set of memory components satisfies the new cadence criterion, applies a memory operation to test reliability of the individual portion and selectively retires the individual portion based on a result of testing the reliability of the individual portion.

The memory controller can determine that the reliability of the individual portion represents failure. In such cases, the memory controller, in response to determining that the reliability of the individual portion represents failure, prevents data from being written to the individual portion. The individual portion can include an individual block stripe.

In some cases, the memory operation includes a SG scan operation. The SG scan monitors a threshold voltage associated with an SG source or SG drain of one or more memory cells of the individual portion. In some examples, the default cadence criterion includes a default threshold number of read operations. In such cases, the memory controller determines that a current measure of read operations performed on the individual portion is less than a specified fraction of the default threshold number of read operations. The memory controller, in response to determining that the current measure of read operations performed on the individual portion is less than a specified fraction of the default threshold number of read operations, accesses a table that associates a first range of measures of read operations with a first threshold and a second range of measures of read operations with a second threshold.

The memory controller determines that the current measure of read operations falls within the second range of measures of read operations. The memory controller, in response to determining that the current measure of read operations falls within the second range of measures of read operations, retrieves the second threshold, and sets the new cadence criterion as the second threshold.

In some cases, the memory controller compares a current quantity of read operations performed on the individual portion to the second threshold and applies the memory operation to test reliability of the individual portion in response to comparing the current quantity of read operations performed on the individual portion to the second threshold. In some examples, the memory controller computes the current measure of read operations as a function of a current quantity of read operations performed on the individual portion and a specified time interval.

In some examples, the default cadence criterion includes a default threshold temperature. In such cases, the memory controller determines that a current temperature measure associated with the individual portion is less than a specified fraction of the default threshold temperature. The memory controller computes the current temperature measure as a function of a current temperature associated with the individual portion and a specified time interval.

The memory controller, in response to determining that the current measure of read operations performed on the individual portion is less than a specified fraction of the default threshold number of read operations, computes a ratio of a current quantity of read operations performed on the individual portion and the default threshold number of read operations. The memory controller adjusts the default cadence criterion by the ratio to compute the new cadence criterion.

The memory controller compares the current quantity of read operations performed on the individual portion to the new cadence criterion corresponding to the default cadence criterion adjusted by the ratio. The memory controller applies the memory operation to test reliability of the individual portion in response to comparing the current quantity of read operations performed on the individual portion to the new cadence criterion.

In some examples, the memory controller determines a current temperature associated with the individual portion. The memory controller accesses a table that associates a first temperature range with a first factor and a second temperature range with a second factor. In some cases, the memory controller retrieves the second factor in response to determining that the current temperature falls within the second temperature range stored in the table and adjusts the ratio by the second factor in response to retrieving the second factor from the table.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples of the present disclosure. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies). Each memory die can include a plurality of planes in which data can be stored or programmed. In some cases, the first memory component 112A can be implemented by a first SSD (or a first independently operable memory sub-system) and the second memory component 112N can be implemented by a second SSD (or a second independently operable memory sub-system). In some cases, each of the memory components 112A to 112N is associated with a respective one of LUN0-N. For example, the first memory component 112A can be associated with a first LUN (referred to as LUN0) and the second memory component 112N can be associated with a second LUN (referred to as LUN1).

In some examples, the memory sub-system 110 is a storage system. A memory sub-system 110 can be a storage device, a memory module, or a hybrid of a storage device and memory module. Examples of a storage device include a SSD, a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-systems 110. FIG. 1 illustrates one example of a host system 120 coupled to one memory sub-system 110. The host system 120 uses the memory sub-system 110, for example, to write (program) data to the memory sub-system 110 and read (retrieve) data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a USB interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCle or CXL interface. The physical host interface can provide an interface for passing control, address, data, and other signals between the memory sub-system 110 and the host system 120.

The memory components 112A to 112N can include any combination of the different types of non-volatile memory components and/or volatile memory components and/or storage devices. An example of non-volatile memory components include a NAND-type flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory. In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), negative-or (NOR) flash memory, electrically erasable programmable read-only memory (EEPROM), and a cross-point array of non-volatile memory cells.

A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages or blocks that can refer to a unit of the memory component 112 used to store data. For example, a single first row that spans a first set of the pages or blocks of the memory components 112A to 112N can correspond to or be grouped as a first block stripe and a single second row that spans a second set of the pages or blocks of the memory components 112A to 112N can correspond to or be grouped as a second block stripe. A single block stripe can be associated with multiple LUNs (e.g., LUN0-N).

A memory sub-system controller 115 can communicate with the memory components 112A to 112N to perform memory operations such as reading data, writing data, or erasing data at the memory components 112A to 112N and other such operations. The memory sub-system controller 115 can communicate with the memory components 112A to 112N to perform various memory management operations, such as enhancement operations, different scan rates, SG scan operations, different scan frequencies, different wear leveling, different read disturb management, garbage collection operations, different near miss ECC operations, and/or different dynamic data refresh. The SG scan operations can be performed to test reliability of a portion or the entirety of a block stripe or portion being tested and/or one or more memory dies. The SG scan operation can apply high and/or low VT voltages to the portion being tested to determine whether the output corresponds to an expected range and/or to modify a VT of the corresponding portions. A result of the SG scan operation can be indicative of failure of the portion being tested and if the portion fails the SG scan operation, the portion being tested and/or the entire block stripe that includes the portion being tested can be marked bad to prevent future writes to the portion and/or block stripe.

The memory sub-system controller 115 can include hardware, such as one or more integrated circuits and/or discrete components, a buffer memory, or a combination thereof. The memory sub-system controller 115 can be a microcontroller, special-purpose logic circuitry (e.g., a FPGA, an ASIC, etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some examples, the local memory 119 can include memory registers storing memory pointers, fetched data, and so forth. The local memory 119 can also include ROM for storing microcode. While the example memory sub-system 110 in FIG. 1 has been illustrated as including the memory sub-system controller 115, in another example of the present disclosure, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112A to 112N. The configuration data can describe the lifetime (maximum) program-erase count (PEC) values and/or reliability grades associated with different groups of the memory components 112A to 112N and/or different blocks within each of the memory components 112A to 112N. The configuration data can also include various manufacturing information for individual memory components of the memory components 112A to 112N. The manufacturing information can specify the reliability metrics/information associated with each memory component. For example, the configuration data can specify one or more default cadence criteria, such as a threshold default number of read operations and/or threshold temperature for triggering performance of the SG scan operations.

Depending on the example, a media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

In some examples, the media operations manager 122 can compute current cadence information for the memory components 112A to 112N or a portion thereof and compare the cadence information (e.g., temperature, PEC count, and/or number of read operations performed in a specified time interval) to the default cadence criterion or criteria. In response to determining that the current cadence information satisfies the default cadence criterion or criteria (e.g., if the current number of read operations performed on a portion of the memory components 112A to 112N transgress a default threshold number of read operations), the media operations manager 122 can perform a memory operation (e.g., an SG scan operation) to test a region or portion (an individual block stripe and/or memory die) of the memory components 112A to 112N. The media operations manager 122 can determine results of the test and selectively retire the portion or return the portion to a free block pool.

In some examples, the commands or operations received from the host system 120 can include a write/read command, which can specify or identify an individual memory component in which to program/read data. Based on the memory component specified by the write/read command, the memory sub-system controller 115 can program/read the data into/from one or more of the memory components 112A to 112N. The memory sub-system controller 115 can be responsible for other memory management operations, such as wear leveling operations, garbage collection operations, error detection and ECC operations, encryption operations, caching operations, and address translations. The memory sub-system controller 115 can further include host interface circuitry to communicate with the host system 120 via the physical host interface. The host interface circuitry can convert the commands received from the host system 120 into command instructions to access the set of memory components 112A to 112N as well as convert responses associated with the set of memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the set of memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which are raw memory devices combined with a local embedded controller (e.g., local media controllers) for memory management within the same memory device package. Any one of the set of memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

In some examples, the media operations manager 122 updates the default cadence criterion or criteria based on current cadence information associated with the set of memory components 112A to 112N. The media operations manager 122 can store the updated cadence criterion or criteria in a table for use in controlling or triggering SG scan operations. For example, the media operations manager 122 can store the updated cadence criterion or criteria as part of the configuration information.

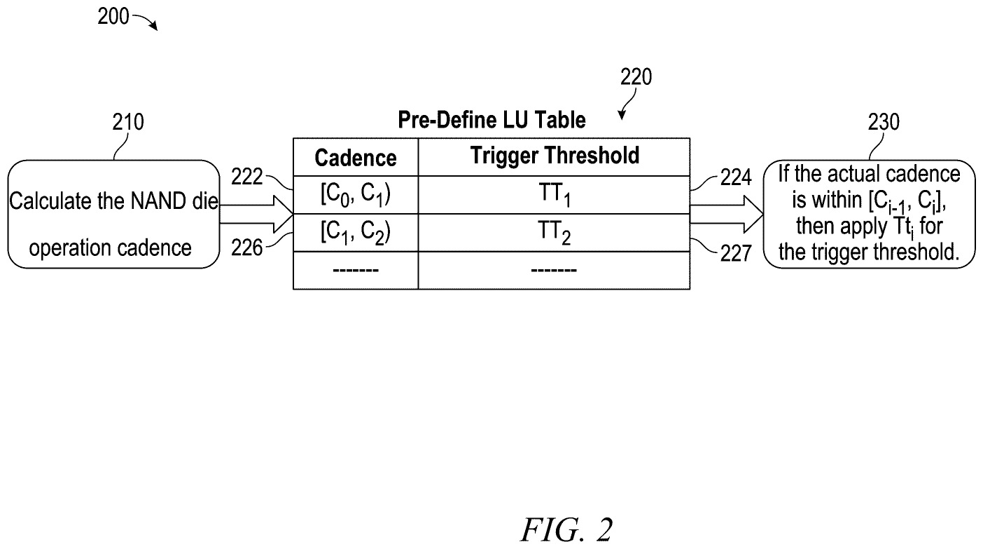

In some cases, the media operations manager 122 can trigger the update to the default cadence criterion or criteria based on one or more conditions being met. For example, the media operations manager 122 can retrieve the default cadence criterion and can compute the one or more conditions as a function of the default cadence criterion. Namely, the current cadence criterion can correspond to a default threshold number of read operations being performed on a region of the set of memory components 112A to 112N. The media operations manager 122 can compute a fraction (e.g., 90%) of the default threshold number of read operations and use that fraction as the one or more conditions. In such cases, the media operations manager 122 can monitor the current number of read operations performed on the region of the set of memory components 112A to 112N. In response to determining that the current number of read operations performed on the region of the set of memory components 112A to 112N transgress the fraction (e.g., 90%) of the default threshold number of read operations, the media operations manager 122 determines that the one or more conditions have been met. In such cases, the media operations manager 122 can perform an operation 210, shown in FIG. 2, to update the default cadence criterion or criteria.

In some examples, the current cadence criterion can correspond to a default temperature of the set of memory components 112A to 112N. The media operations manager 122 can compute a fraction (e.g., 90%) of the default temperature and use that fraction as another one of the one or more conditions. In such cases, the media operations manager 122 can monitor the current temperature of the region of the set of memory components 112A to 112N. In response to determining that the current temperature of the set of memory components 112A to 112N transgresses the fraction (e.g., 90%) of the default temperature, the media operations manager 122 determines that the one or more conditions have been met. In such cases, the media operations manager 122 can perform an operation 210, shown in FIG. 2, to update the default cadence criterion or criteria.

As part of the operation 210, the media operations manager 122 obtains current cadence information associated with the set of memory components 112A to 112N (or some portion or region of the set of memory components 112A to 112N). For example, the media operations manager 122 can compute a current measure of read operations performed on the set of memory components 112A to 112N. The measure of the read operations can be computed as a function of the current number of read operations performed in a specified time interval (e.g., representing a current read frequency associated with the set of memory components 112A to 112N). For example, the current number of read operations can be divided by a difference between two points in time to compute the measure of read operations.

The media operations manager 122 can then access a look-up table 220 that may be stored as part of the configuration information. The look-up table 220 can associate different ranges of cadence values (e.g., different ranges of read frequencies) with respective trigger thresholds. For example, a first range of read measures or read frequencies 222 can be associated with a first trigger threshold 224. A second range of read measures or read frequencies 226 can be associated with a second trigger threshold 227.

In some cases, the media operations manager 122 determines that the current measure of read operations falls within the first range of read measures or read frequencies 222. In response, the media operations manager 122 retrieves the first trigger threshold 224. The media operations manager 122 can directly use the first trigger threshold 224 to control decisions to perform SG scan operations at operation 230. For example, the media operations manager 122 can later obtain a current number of read operations performed on the set of memory components 112A to 112N (or portion or region thereof). The media operations manager 122 can compare the current number of read operations to the first trigger threshold 224 instead of the default number of read operations. In response to determining that the current number of read operations transgress the first trigger threshold 224, the media operations manager 122 performs the SG scan operations on the set of memory components 112A to 112N (or portion or region thereof). If not, the media operations manager 122 can periodically continue comparing the current number of read operations to the first trigger threshold 224 to control performing the SG scan operations.

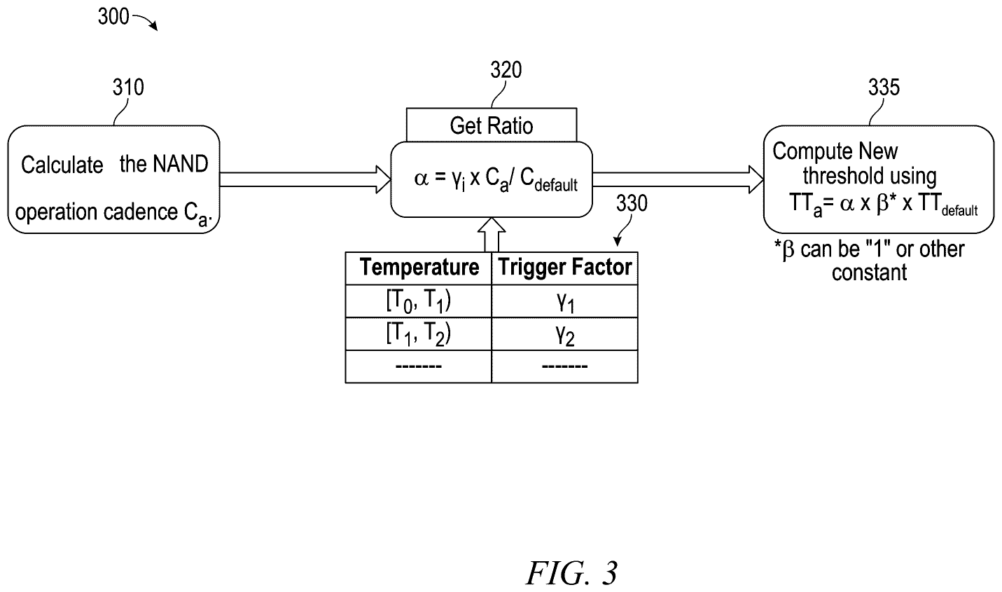

In some cases, after retrieving the threshold from the look-up table 220 based on determining whether the current measure of read operations falls within one of the ranges in the look-up table 220 (e.g., the first range of read measures or read frequencies 222 or the second range of read measures or read frequencies 226), the media operations manager 122 adjusts the threshold by a temperature-related factor. For example, the media operations manager 122 accesses the current temperature of the set of memory components 112A-112N. The media operations manager 122 can access a temperature table (e.g., temperature table 330 shown in FIG. 3) to retrieve a corresponding temperature factor. The media operations manager 122 can then adjust (e.g., multiply) the retrieved threshold by the retrieved temperature factor. The adjusted retrieved threshold can then be used to control performing the SG scan operations, as discussed above.

In some examples, the default cadence criterion can be adjusted based on a current cadence criterion and/or the temperature factor. For example, the media operations manager 122 can determine that the current number of read operations performed on the region of the set of memory components 112A to 112N transgresses the fraction (e.g., 90%) of the default threshold number of read operations. In such cases, the media operations manager 122 determines that the one or more conditions have been met for updating the default cadence criterion. In response, the media operations manager 122 can perform an operation 310, shown in FIG. 3, to update the default cadence criterion or criteria.

The media operations manager 122, after performing operation 310, obtains current cadence information associated with the set of memory components 112A to 112N (or some portion or region of the set of memory components 112A to 112N). For example, the media operations manager 122 can compute a current measure of read operations performed on the set of memory components 112A to 112N. The media operations manager 122 can compute a ratio of the current measure of read operations to the default cadence criterion at operation 320. The ratio of the current measure of read operations to the default cadence criterion computed at operation 320 is then used at operation 335 to control performing the SG scan operations.

For example, the media operations manager 122 can later obtain a current number of read operations performed on the set of memory components 112A to 112N (or portion or region thereof). The media operations manager 122 can compare the current number of read operations to the ratio computed at operation 320 instead of the default cadence number of read operations. In response to determining that the current number of read operations transgresses the ratio, the media operations manager 122 performs the SG scan operations on the set of memory components 112A to 112N (or portion or region thereof). If not, the media operations manager 122 can periodically continue comparing the current number of read operations to the first trigger threshold 224 to control performing the SG scan operations.

In some cases, after computing the ratio at operation 320, the media operations manager 122 adjusts the ratio by a temperature-related factor. For example, the media operations manager 122 accesses the current temperature of the set of memory components 112A-112N. The media operations manager 122 can access the temperature table 330 to retrieve a corresponding temperature factor. The temperature table 330 can associate a first range of temperatures with a first temperature factor and a second range of temperatures with a second temperature factor. The media operations manager 122 can retrieve the first temperature factor from the temperature table 330 in response to determining that the current temperature of the set of memory components 112A to 112N falls within the first range of temperatures. The media operations manager 122 can then adjust (e.g., multiply) the computed ratio of the current cadence measure to the default cadence measure by the retrieved temperature factor. The adjusted retrieved threshold can then be used to control performing the SG scan operations, as discussed above.

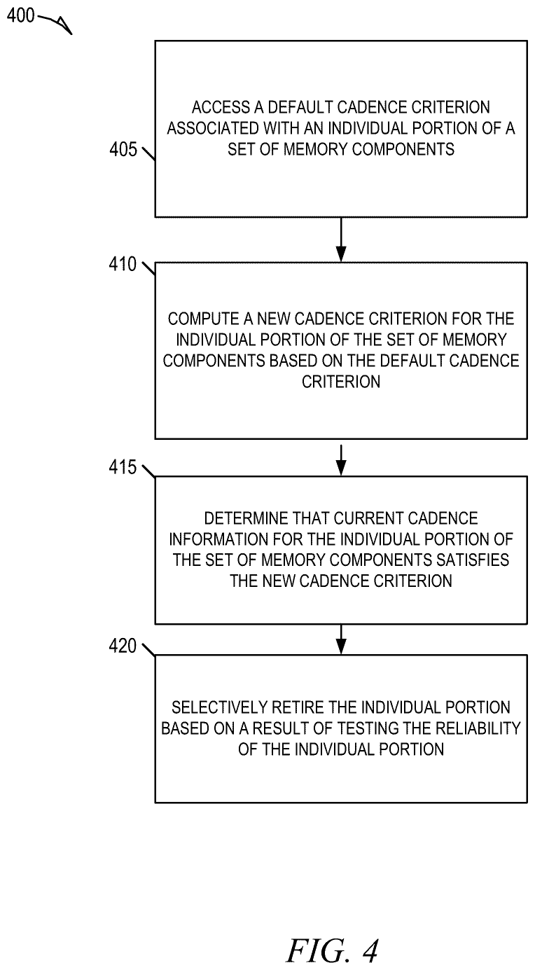

FIG. 4 is a flow diagram of an example method 400 for performing adaptive media management operations, in accordance with some implementations of the present disclosure. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 400 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method 400 (or process) begins at operation 405, with a media operations manager 122 of a memory sub-system (e.g., memory sub-system 110) accessing a default cadence criterion associated with an individual portion of a set of memory components. Then, at operation 410, the media operations manager 122 computes a new cadence criterion for the individual portion of the set of memory components based on the default cadence criterion and, at operation 415, determines that current cadence information for the individual portion of the set of memory components satisfies the new cadence criterion. At operation 420, the media operations manager 122 selectively retires the individual portion based on a result of testing the reliability of the individual portion, such as in response to determining that current cadence information for the individual portion of the set of memory components satisfies the new cadence criterion, and applying a memory operation to test reliability of the individual portion.

In view of the disclosure above, various examples are set forth below. It should be noted that one or more features of an example, taken in isolation or combination, should be considered within the disclosure of this application.

Example 1. A system comprising: a set of memory components of a memory sub-system; and at least one processing device operatively coupled to the set of memory components, the at least one processing device being configured to perform operations comprising: accessing a default cadence criterion associated with an individual portion of the set of memory components; computing a new cadence criterion for the individual portion of the set of memory components based on the default cadence criterion; determining that current cadence information for the individual portion of the set of memory components satisfies the new cadence criterion; in response to determining that current cadence information for the individual portion of the set of memory components satisfies the new cadence criterion, applying a memory operation to test reliability of the individual portion; and selectively retiring the individual portion based on a result of testing the reliability of the individual portion.

Example 2. The system of Example 1, the operations comprising: determining that the reliability of the individual portion represents failure.

Example 3. The system of Example 2, the operations comprising: in response to determining that the reliability of the individual portion represents failure, preventing data from being written to the individual portion.

Example 4. The system of any one of Examples 1-3, wherein the individual portion comprises an individual block stripe.

Example 5. The system of any one of Examples 1-4, wherein the memory operation comprises a SG scan operation, the SG scan monitoring a threshold voltage associated with an SG source or SG drain of one or more memory cells of the individual portion.

Example 6. The system of any one of Examples 1-5, wherein the default cadence criterion comprises a default threshold number of read operations, the operations comprising: determining that a current measure of read operations performed on the individual portion is less than a specified fraction of the default threshold number of read operations.

Example 7. The system of Example 6, the operations comprising: in response to determining that the current measure of read operations performed on the individual portion is less than a specified fraction of the default threshold number of read operations, accessing a table that associates a first range of measures of read operations with a first threshold and a second range of measures of read operations with a second threshold.

Example 8. The system of Example 7, the operations comprising: determining that the current measure of read operations falls within the second range of measures of read operations; in response to determining that the current measure of read operations falls within the second range of measures of read operations, retrieving the second threshold; and setting the new cadence criterion as the second threshold.

Example 9. The system of Example 8, the operations comprising: comparing a current quantity of read operations performed on the individual portion to the second threshold; and applying the memory operation to test reliability of the individual portion in response to comparing the current quantity of read operations performed on the individual portion to the second threshold.

Example 10. The system of any one of Examples 6-9, the operations comprising: computing the current measure of read operations as a function of a current quantity of read operations performed on the individual portion and a specified time interval.

Example 11. The system of any one of Examples 6-10, wherein the default cadence criterion comprises a default threshold temperature, the operations comprising: determining that a current temperature measure associated with the individual portion is less than a specified fraction of the default threshold temperature.

Example 12. The system of Example 11, the operations comprising: computing the current temperature measure as a function of a current temperature associated with the individual portion and a specified time interval.

Example 13. The system of any one of Examples 6-12, the operations comprising: in response to determining that the current measure of read operations performed on the individual portion is less than a specified fraction of the default threshold number of read operations, computing a ratio of a current quantity of read operations performed on the individual portion and the default threshold number of read operations.

Example 14. The system of Example 13, the operations comprising: adjusting the default cadence criterion by the ratio to compute the new cadence criterion.

Example 15. The system of Example 14, the operations comprising: comparing the current quantity of read operations performed on the individual portion to the new cadence criterion corresponding to the default cadence criterion adjusted by the ratio; and applying the memory operation to test reliability of the individual portion in response to comparing the current quantity of read operations performed on the individual portion to the new cadence criterion.

Example 16. The system of any one of Examples 13-15, the operations comprising: determining a current temperature associated with the individual portion; and accessing a table that associates a first temperature range with a first factor and a second temperature range with a second factor.

Example 17. The system of Example 16, the operations comprising: retrieving the second factor in response to determining that the current temperature falls within the second temperature range stored in the table; and adjusting the ratio by the second factor in response to retrieving the second factor from the table.

Methods and computer-readable storage medium with instructions for performing any one of the above Examples.

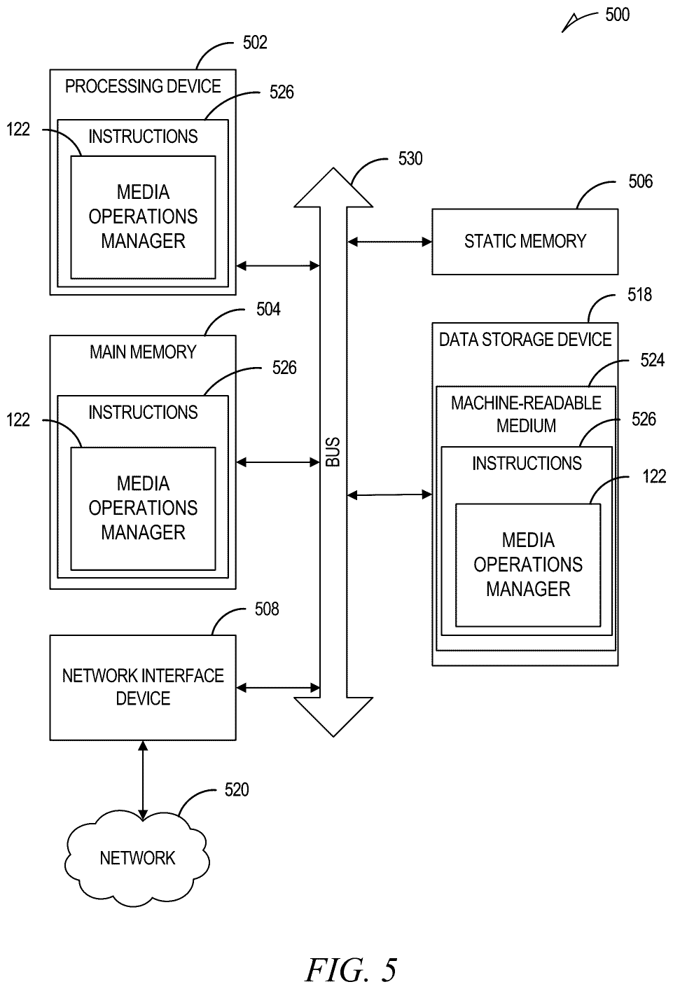

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an ASIC, a FPGA, a digital signal processor (DSP), a network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one example, the instructions 526 implement functionality corresponding to the media operations manager 122 of FIG. 1. While the machine-readable storage medium 524 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; ROMs; RAMs; erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine-readable (e.g., computer-readable) storage medium such as a ROM, RAM, magnetic disk storage media, optical storage media, flash memory components, and so forth.

In the foregoing specification, the disclosure has been described with reference to specific examples thereof. It will be evident that various modifications can be made thereto without departing from the broader scope of the disclosure as set forth in the following claims. The specification and drawings are, accordingly, to be regarded in an illustrative sense rather than a restrictive sense.

What is claimed is:

1. A system comprising:
a set of memory components of a memory sub-system; and
at least one processing device operatively coupled to the set of memory components, the at least one processing device being configured to perform operations comprising:
accessing a default cadence criterion associated with an individual portion of the set of memory components;
computing a new cadence criterion for the individual portion of the set of memory components based on the default cadence criterion;
determining that current cadence information for the individual portion of the set of memory components satisfies the new cadence criterion;
in response to determining that current cadence information for the individual portion of the set of memory components satisfies the new cadence criterion, applying a memory operation to test reliability of the individual portion; and
selectively retiring the individual portion based on a result of testing the reliability of the individual portion.

2. The system of claim 1, the operations comprising:
determining that the reliability of the individual portion represents failure.

3. The system of claim 2, the operations comprising:
in response to determining that the reliability of the individual portion represents failure, preventing data from being written to the individual portion.

4. The system of claim 1, wherein the individual portion comprises an individual block stripe.

5. The system of claim 1, wherein the memory operation comprises a select gate (SG) scan operation, the SG scan monitoring a threshold voltage associated with an SG source or SG drain of one or more memory cells of the individual portion.

6. The system of claim 1, wherein the default cadence criterion comprises a default threshold number of read operations, the operations comprising:
determining that a current measure of read operations performed on the individual portion is less than a specified fraction of the default threshold number of read operations.

7. The system of claim 6, the operations comprising:
in response to determining that the current measure of read operations performed on the individual portion is less than a specified fraction of the default threshold number of read operations, accessing a table that associates a first range of measures of read operations with a first threshold and a second range of measures of read operations with a second threshold.

8. The system of claim 7, the operations comprising:
determining that the current measure of read operations falls within the second range of measures of read operations;
in response to determining that the current measure of read operations falls within the second range of measures of read operations, retrieving the second threshold; and
setting the new cadence criterion as the second threshold.

9. The system of claim 8, the operations comprising:
comparing a current quantity of read operations performed on the individual portion to the second threshold; and
applying the memory operation to test reliability of the individual portion in response to comparing the current quantity of read operations performed on the individual portion to the second threshold.

10. The system of claim 6, the operations comprising:
computing the current measure of read operations as a function of a current quantity of read operations performed on the individual portion and a specified time interval.

11. The system of claim 6, wherein the default cadence criterion comprises a default threshold temperature, the operations comprising:
determining that a current temperature measure associated with the individual portion is less than a specified fraction of the default threshold temperature.

12. The system of claim 11, the operations comprising:
computing the current temperature measure as a function of a current temperature associated with the individual portion and a specified time interval.

13. The system of claim 6, the operations comprising:
in response to determining that the current measure of read operations performed on the individual portion is less than a specified fraction of the default threshold number of read operations, computing a ratio of a current quantity of read operations performed on the individual portion and the default threshold number of read operations.

14. The system of claim 13, the operations comprising:
adjusting the default cadence criterion by the ratio to compute the new cadence criterion.

15. The system of claim 14, the operations comprising:
comparing the current quantity of read operations performed on the individual portion to the new cadence criterion corresponding to the default cadence criterion adjusted by the ratio; and
applying the memory operation to test reliability of the individual portion in response to comparing the current quantity of read operations performed on the individual portion to the new cadence criterion.

16. The system of claim 13, the operations comprising:
determining a current temperature associated with the individual portion; and
accessing a table that associates a first temperature range with a first factor and a second temperature range with a second factor.

17. The system of claim 16, the operations comprising:
retrieving the second factor in response to determining that the current temperature falls within the second temperature range stored in the table; and
adjusting the ratio by the second factor in response to retrieving the second factor from the table.

18. A method comprising:
accessing a default cadence criterion associated with an individual portion of a set of memory components;
computing a new cadence criterion for the individual portion of the set of memory components based on the default cadence criterion;
determining that current cadence information for the individual portion of the set of memory components satisfies the new cadence criterion;
in response to determining that current cadence information for the individual portion of the set of memory components satisfies the new cadence criterion, applying a memory operation to test reliability of the individual portion; and
selectively retiring the individual portion based on a result of testing the reliability of the individual portion.

19. The method of claim 18, comprising:
determining that the reliability of the individual portion represents failure.

20. A non-transitory computer-readable storage medium comprising instructions that, when executed by at least one processing device, cause the at least one processing device to perform operations comprising:
accessing a default cadence criterion associated with an individual portion of a set of memory components;
computing a new cadence criterion for the individual portion of the set of memory components based on the default cadence criterion;
determining that current cadence information for the individual portion of the set of memory components satisfies the new cadence criterion;
in response to determining that current cadence information for the individual portion of the set of memory components satisfies the new cadence criterion, applying a memory operation to test reliability of the individual portion; and
selectively retiring the individual portion based on a result of testing the reliability of the individual portion.
